(19) United States
(12) Patent Application Publication
(10) Pub. No.: US 2025/0089165 A1
(43) Pub. Date: Mar. 13, 2025

(54) PRINTED CIRCUIT BOARD

(71) Applicant: SAMSUNG ELECTRO-MECHANICS CO., LTD., Suwon-si (KR)

(72) Inventors: Seong Hun NA, Suwon-si (KR); Dong Yong KIM, Suwon-si (KR); Mi Geum KIM, Suwon-si (KR); Mi Jung PARK, Suwon-si (KR); Yong Su LEE, Suwon-si (KR); Ho Seung JANG, Suwon-si (KR); Sang Ik CHO, Suwon-si (KR); Sung HAN, Suwon-si (KR); Sung Hoon KIM, Suwon-si (KR)

(73) Assignee: SAMSUNG ELECTRO-MECHANICS CO., LTD., Suwon-si (KR)

(21) Appl. No.: 18/673,686

(22) Filed: May 24, 2024

(30) Foreign Application Priority Data
Sep. 11, 2023 (KR) 10-2023-0120274
Oct. 31, 2023 (KR) 10-2023-0147587

(51) Int. Cl. H05K 1/11; H05K 1/03

(52) U.S. Cl. CPC H05K 1/115; H05K 1/0306; H05K 2201/0323; H05K 2201/09827

(57) ABSTRACT

A printed circuit board includes a glass layer, a through-hole penetrating through the glass layer, a seed layer provided along an inner wall of the through-hole, and a through-via disposed on the seed layer and filling the through-hole. The seed layer includes a carbon-based conductive material.

### CROSS-REFERENCE TO RELATED APPLICATION(S)

This application claims benefit of priority to Korean Patent Application No. 10-2023-0147587 filed on Oct. 31, 2023 and Korean Patent Application No. 10-2023-0120274 filed on Sep. 11, 2023 in the Korean Intellectual Property Office, the disclosures of which are incorporated herein by reference in their entirety.

### TECHNICAL FIELD

The present disclosure relates to printed circuit boards.

A multi-chip package including memory chips such as a High Bandwidth Memory (HBM) for processing exponentially increased data, processor chips such as Central Processing Unit (CPU), Graphics Processing Unit (GPU), Application Specific Integrated Circuit (ASIC), Field Programmable Gate Array (FPGA), and the like, has been being used due to recent developments in artificial intelligence (AI) technology, and the like. Accordingly, attempts to use glass materials are continuing. However, glass materials have a problem in that adhesion thereof with metal materials decreases, causing problems when using glass substrates.

### SUMMARY

An aspect of the present disclosure is to provide a printed circuit board including a glass layer.

An aspect of the present disclosure is to provide a printed circuit board in which adhesion between a glass layer and a metal material may be secured.

An aspect of the present disclosure is to provide a printed circuit board having improved reliability.

According to an aspect of the present disclosure, a printed circuit board includes a glass layer, a through-hole penetrating through the glass layer, a seed layer provided along an inner wall of the through-hole, and a through-via disposed on the seed layer and filling the through-hole. The seed layer includes a carbon-based conductive material.

According to an aspect of the present disclosure, a printed circuit board includes a glass layer, a through-via penetrating through an upper surface and a lower surface of the glass layer, and a seed layer disposed between the through-via and the glass layer. The seed layer includes at least one of a conductive polymer material and a carbon-based conductive material, and an upper surface of the through-via is substantially coplanar with the upper surface of the glass layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board; and

FIGS. 4 to 10 are cross-sectional views schematically illustrating various embodiments of a glass layer of a printed circuit board and a method of manufacturing the same.

### DETAILED DESCRIPTION

Hereinafter, the present disclosure will be described with reference to the accompanying drawings. The shapes and sizes of elements in the drawings may be exaggerated or reduced for clearer descriptions.

### Electronic Device

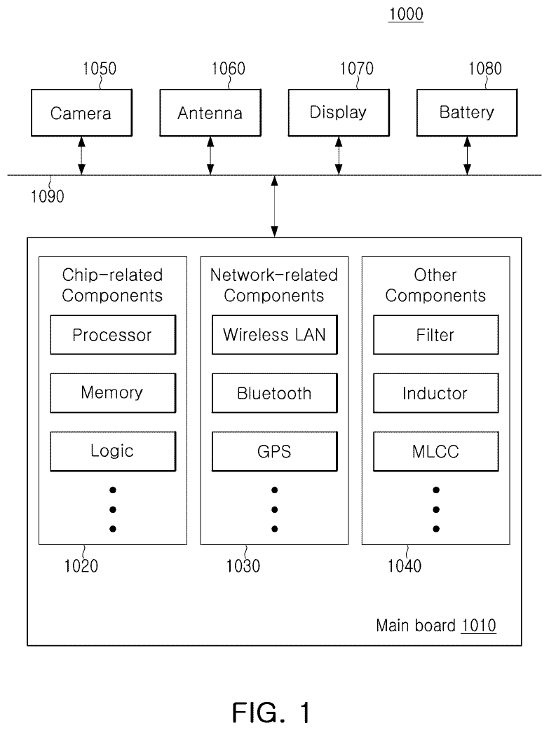

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related electronic components. In addition, the chip related components 1020 may also be combined with each other. The chip related components 1020 may be in the form of a package including the above-described chips or electronic components.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, or the like. In addition, other components 1040 may also be combined with each other, with the chip related components 1020 or the network related components 1030 described above.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like. However, these other electronic components are not limited thereto, and may also be an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, other electronic components for various uses may also be included depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

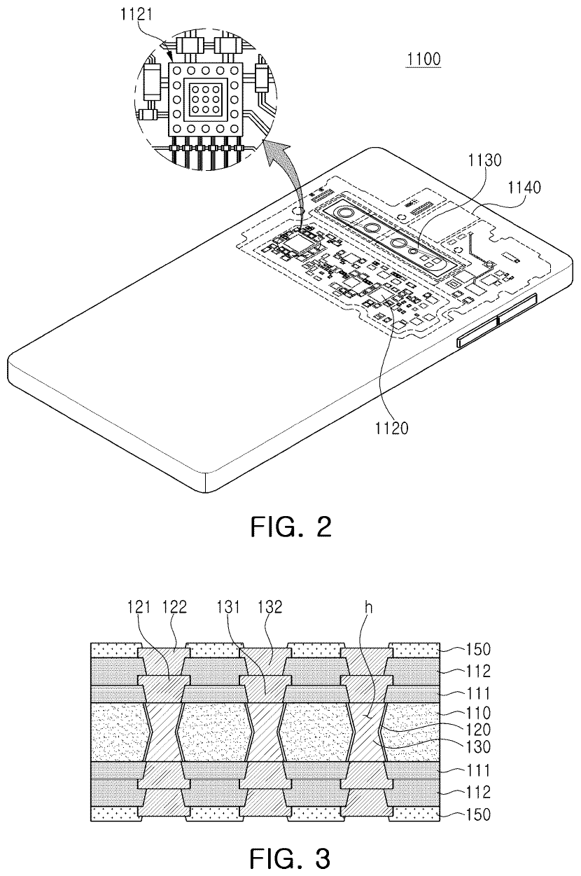

FIG. 2 is a schematic perspective view illustrating an example of an electronic device.

Referring to FIG. 2, the electronic device may be, for example, a smartphone 1100. A motherboard 1110 is accommodated inside the smartphone 1100, and various components 1120 are physically or electrically connected to the motherboard 1110. In addition, other components that may or may not be physically or electrically connected to the motherboard 1110, such as a camera module 1130 and/or a speaker 1140, may be accommodated therein. Some of the electronic components 1120 may be the above-described chip related components, for example, a component package 1121, but are not limited thereto. The component package 1121 may be in the form of a printed circuit board on which electronic components including active components and/or passive components are surface mounted. Alternatively, the component package 1121 may be in the form of a printed circuit board in which active components and/or passive components are embedded. On the other hand, the electronic device is not necessarily limited to the smartphone 1100, and may also be other electronic devices as described above.

### Printed Circuit Board

FIG. 3 is a cross-sectional view schematically illustrating an example of a printed circuit board.

Referring to FIG. 3, a printed circuit board according to some embodiments of the disclosure may include a glass layer 110, a through-hole h penetrating through the upper and lower surfaces of the glass layer 110, a seed layer 120 formed on a surface of the inner wall of the through-hole h, and a through-via 130 disposed on the seed layer 120 and filling the through-hole h.

The glass layer 110 may include glass, which is an amorphous solid. Glass may include, for example, pure silicon dioxide (about 100% SiO₂), soda lime glass, borosilicate glass, alumino-silicate glass, etc., but the present disclosure is not limited thereto, and alternative glass materials such as fluorine glass, phosphate glass, chalcogen glass, etc. may also be used as materials for the glass layer 110. Additionally, other additives may be further included to form glass with specific physical properties. These additives may include calcium carbonate (for example, lime) and sodium carbonate (for example, soda), as well as magnesium, calcium, manganese, aluminum, lead, boron, iron, chromium, potassium, sulfur and antimony, and carbonates and/or oxides of these elements and other elements. The glass layer 110 is a layer that is distinct from materials containing glass fiber (glass fiber, glass cloth, glass fabric), such as copper clad laminate (CCL), prepreg (PPG), etc. and for example, may be understood as plate glass, or the like. The glass layer 110 may be a plate glass supported by a support such as another core or the like.

A printed circuit board according to some examples includes the glass layer 110, and may thus basically have excellent flatness, and additionally, may be advantageous for warpage control through low coefficient of thermal expansion (CTE) or the like. In detail, since the printed circuit board according to some examples may have the glass layer 110 as a core layer, it may be advantageous for warpage control even in the operation of stacking other insulating layers. In addition, even if other insulating layers are stacked simultaneously or sequentially on the glass layer 110, the flatness may be further improved, and therefore, it may be more advantageous for forming high-density fine circuits with fine pitch. In addition, by employing the glass layer 110, the number of layers of the printed circuit board may be reduced and design freedom may be further improved through the characteristics of glass having variable dielectric properties, for example, Dk of 2.5 to 11.

The through-hole h formed in the glass layer 110 may penetrate the upper and lower surfaces of the glass layer 110. As the through-hole h may penetrate the upper and lower surfaces of the glass layer 110, the wiring layer disposed above the glass layer 110 and the wiring layer disposed on the lower side of the glass layer 110 may be connected. The through-hole h may be formed through various methods such as laser processing, mechanical processing, chemical processing and the like, and the through-hole h may also be formed by combining multiple processing methods rather than a single processing method.

The through-hole h may be formed so that the widths of the upper and lower surfaces are respectively wider than the width of the center. For example, the through-hole h may have a tapered shape to have the narrowest width at the center of the glass layer 110 and to widen in the widths at the top and bottom surfaces of the glass layer 110. For example, the through-hole h may have an hourglass-like shape. However, the present disclosure is not necessarily limited thereto, and the through-hole may have a tapered shape so that the width at the bottom becomes narrower than the width at the top. Additionally, the present disclosure is not limited thereto, and the through-hole h may have a non-tapered pillar shape. The cross-sectional shape of the through-hole h may be circular, but is not necessarily limited thereto and may have various shapes such as ellipse and polygon.

The printed circuit board according to some examples of the present disclosure may include a seed layer 120 formed along the inner wall of the through-hole h. The seed layer 120 may function as a seed for forming the through-via 130 and may be used as a plating lead-in line for electroplating. The seed layer 120 may include a conductive polymer material, such as a carbon-based conductive material, a conductive polymer or the like.

Carbon-based conductive materials may refer to carbon-based inorganic materials and may include, for example, carbon black materials, but the carbon-based conductive material is not necessarily limited thereto, and may include at least one material among graphite, graphene, carbon nanotube (CNT), and fullerene, but is not necessarily limited thereto. In addition, any material that contains a carbon-based inorganic material and has electrical conductivity may be used without limitation. Carbon black, an example of carbon-based conductive materials, is one of the by-products obtained by burning carbon materials and may have electrical conductivity. By adding other additives to the carbon material having black such electrical conductivity, the electrical conductivity may be further increased and the bonding strength with the glass layer 110 may be increased. When the seed layer 120 includes a carbon-based conductive material, the seed layer 120 may be formed by coating the glass layer 110 using a coating solution containing a carbon-based conductive material. At this time, the seed layer 120 may be formed on the top, bottom, and side surfaces of the glass layer 110. Since the operation of removing another part of the seed layer 120 may be further included, the seed layer 120 of the printed circuit board according to some examples may be formed only on the inner wall of the through-hole h of the glass layer 110, which will be described in detail later in a method of manufacturing the printed circuit board.

A conductive polymer may include a polymer composed of an organic material that has electrical conductivity. The conductive polymer may include, but is not necessarily limited to, at least one selected from the group consisting of, for example, Poly(3,4-ethylenedioxythiophene), poly(styrenesulfonate) (PEDOT:PSS), polyaniline, polyindole, and polypyrrole. Additionally, any organic material with electrical conductivity may be used without limitation. Even if the seed layer 120 includes a conductive polymer, it may be formed through coating.

In the printed circuit board according to some examples, the seed layer 120 may not include copper. If the seed layer 120 contains copper, adhesion of the seed layer 120 with the glass layer 110 may be weak. In detail, because the adhesion between copper and the glass layer is weak, the phenomenon of peeling of the seed layer from the glass layer may occur when manufacturing the build-up layer, or the problem of copper being separated from the finished substrate may also occur. If the seed layer 120 is formed through deposition such as sputtering or the like without using copper to ensure adhesion, it may take a lot of time and cost. On the other hand, the printed circuit board according to some examples may include a carbon-based conductive material or a conductive polymer as described above, and therefore, the seed layer 120 may be formed using a low-cost process while ensuring adhesion between the seed layer 120 and the glass layer 110. In detail, the printed circuit board according to some examples may implement a seed layer 120 that functions as a plating lead-in line without containing metal. Since the seed layer 120 does not contain a metal, the problem of irregular plating occurring due to loss or damage of the seed layer 120 due to pretreatment performed before electroplating may be prevented, which may be more advantageous in securing adhesion to the glass layer 110.

The printed circuit board according to some examples includes a through-via 130 disposed on the seed layer 120 and disposed to fill the through-hole h. The through-via 130 may have the same shape as the through-hole h.

The through-via 130 may include a metal selected from the group consisting of copper (Cu), aluminum (Al), silver (Ag), tin (Sn), gold (Au), nickel (Ni), lead (Pb), titanium (Ti), and alloys thereof. According to some embodiments, the through-via 130 may include copper (Cu), but is not limited thereto. Each wiring layer may perform various functions depending on the design, and for example, may include signal vias, power vias, ground vias, and the like.

The through-via 130 may be formed by performing plating using the seed layer 120 as a plating lead-in line. The plating may be electroplating, in which case through-vias may be formed with electro-copper, but is not necessarily limited thereto. For example, after forming an electroless plating layer (or chemical copper) on the seed layer 120, electroplating (or electroplating) may be performed. In FIG. 3, the through-via 130 is illustrated as a so-called filled via, which fills the through-hole h of the glass layer 110 with a metal layer, but is not limited thereto. A detailed method of forming the through-via 130, which may be a conformal via disposed along the wall of the via hole, is not limited thereto. For example, it is not limited to what is illustrated in FIG. 3, and the through-via 130 may be formed by forming a thin plating layer on the inner wall of the through-hole h, filling the same with paste, and then firing. At this time, the plug may contain ink of an insulating material, but is not necessarily limited thereto.

The upper surface of the through-via 130 may be substantially coplanar with the upper surface of the glass layer 110, and the lower surface of the through-via 130 may be substantially coplanar with the lower surface of the glass layer 110. By including the operation of planarizing the glass layer 110 and the through-via 130 after forming the through-via 130 in the through-hole h of the glass layer 110, the upper and lower surfaces of the glass layer 110 may be substantially coplanar with the upper and lower surfaces of the through-via 130. The operation of planarizing the glass layer 110 and the through-via 130 may be performed by a chemical-mechanical polishing (CMP) process, but is not necessarily limited thereto, and any method for flattening the glass layer 110 and the like, such as polishing or grinding, may be used without limitation. Because the upper surface of the through-via 130 may be polished together with the upper surface of the glass layer 110, the surface roughness of the upper surface of the glass layer 110 may be substantially the same as the surface roughness of the upper surface of the through-via 130. Similarly, in the case of the lower surface of the through-via 130 and the lower surface of the glass layer 110, the surface roughness of the lower surface of the glass layer 110 may be substantially the same as the surface roughness of the lower surface of the through-via 130, but the present disclosure is not necessarily limited thereto.

According to some embodiments of the present disclosure, in the process of planarizing the glass layer 110 and the through-via 130, a portion of the seed layer 120 disposed on the upper surface of the glass layer 110 may be removed, and electrically unnecessary portions are open, allowing functions such as signal transmission of the board to be performed. Since the seed layer 120 along with the glass layer 110 and the through-via 130 may also be flattened, the upper surface of the seed layer 120 may also be substantially coplanar with the upper surface of the glass layer 110 and the upper surface of the through-via 130, and the lower surface of the seed layer 120 may also be substantially coplanar with the lower surface of the glass layer 110 and the lower surface of the through-via 130. In this case, the upper and lower surfaces of the seed layer 120 may refer to the surfaces exposed to the upper and lower surfaces of the glass layer 110, respectively. For example, in the case of a shape in a top view of the glass layer 110, the upper surface of the through-via 130 is located within the glass layer 110, and the upper surface of the seed layer 120 may be positioned along the periphery of the through-via 130. The glass layer 110 may also have the same shape in a plan view viewed from the bottom of the seed layer. As used herein, the term “substantially” means a small, insignificant amount from absolute or perfect conditions, dimensions, measurements, results, etc., would be expected by one skilled in the art, but which does not significantly affect overall performance and allow for variation. “Substantially” when used for a number or parameter or property that can be expressed as a number means within 10 percent.

The printed circuit board according to an example may further include a first insulating layer 111 and a second insulating layer 112 disposed on the glass layer 110, and may further include a first wiring layer 121 disposed on the first insulating layer 111, a second wiring layer 122 disposed on the second insulating layer 112, a first via layer 131 penetrating through at least a portion of the first insulating layer 111 to connect the first wiring layer 121 and the through-via 130 to each other, and a second via layer 132 penetrating through at least a portion of the second insulating layer 112 to connect the second wiring layer 122 and the first wiring layer 121 to each other.

The first insulating layer 111 and the second insulating layer 112 may each include an organic insulating material. Organic insulating materials may include thermosetting resins such as epoxy resins, thermoplastic resins such as polyimide, or materials including resins containing inorganic fillers, organic fillers, and/or glass fibers (glass fiber, glass cloth, glass fabric) along with resins. For example, the insulating material may include a non-photosensitive insulating material such as Ajinomoto Build-up Film (ABF) or prepreg (PPG), but is not limited thereto. In addition, other polymer materials may be used. Additionally, the insulating material may include a photosensitive insulating material such as Photo Imagable Dielectric (PID). Additionally, the insulating material may include an adhesive sheet such as Bonding Sheet (BS) or the like.

The first insulating layer 111 and the second insulating layer 112 may include the same insulating material, and in detail, the first insulating layer 111 and the second insulating layer 112 may each include Ajinomoto Build-up Film (ABF), but are not limited thereto. The first insulating layer 111 and the second insulating layer 112 may also contain other organic insulating materials, but are not limited thereto. Additionally, the first insulating layer 111 and the second insulating layer 112 may also include different materials.

On the other hand, in FIG. 3, the first insulating layer 111 and the second insulating layer 112 are each illustrated as one layer of insulating layer, but this is not necessarily limited. If necessary, the first insulating layer 111 and the second insulating layer 112 may include multiple insulating layers. In addition, the thicknesses of the first insulating layer 111 and the second insulating layer 112 may not be substantially the same, and the second insulating layer 112 disposed above the glass layer 110 may be comprised of a relatively thinner insulating layer for fine circuits, or the like, and may also further include additional configurations that may be used by those skilled in the art.

The first wiring layer 121 and the second wiring layer 122 may each include a metal. The metal may include at least one selected from the group consisting of copper (Cu), aluminum (Al), silver (Ag), tin (Sn), gold (Au), nickel (Ni), lead (Pb), titanium (Ti), and alloys thereof. In detail, the metal may include copper (Cu), but the present disclosure is not limited thereto. The first wiring layer 121 and the second wiring layer 122 may independently perform various functions depending on the design. For example, the first wiring layer 121 and the second wiring layer 122 may include signal patterns, power patterns, ground patterns, and the like. These patterns may have various forms such as lines, planes, and pads. The first wiring layer 121 and the second wiring layer 122 may respectively include an electroless plating layer (or chemical copper) and an electrolytic plating layer (or electrical copper), or may include a metal foil (or copper foil) and an electrolytic plating layer (or electrolytic copper). Alternatively, the first wiring layer 121 and the second wiring layer 122 may include a metal foil (or copper foil), an electroless plating layer (or chemical copper), and an electrolytic plating layer (or electrolytic copper). A sputtering layer may be included instead of an electroless plating layer (or chemical copper), and both may be included if necessary.

The first via layer 131 and the second via layer 132 may each include a metal. The metal may include at least one selected from the group consisting of copper (Cu), aluminum (Al), silver (Ag), tin (Sn), gold (Au), nickel (Ni), lead (Pb), titanium (Ti), and alloys thereof, etc. According to some embodiments of the present disclosure, the first via layer 131 and the second via layer 132 each may include copper (Cu), but is not limited thereto. The first via layer 131 and the second via layer 132 may each include a filled via that fills the via hole, but may also include a conformal via disposed along the wall of the via hole. The first via layer 131 and the second via layer 132 may perform various functions depending on the design, and for example, may include ground vias, power vias, signal vias, and the like. The first and second connection vias 131 and 132 may include an electroless plating layer (or chemical copper) and an electrolytic plating layer (or electrical copper). A sputtering layer may be included instead of an electroless plating layer (or chemical copper), and both may be included if necessary.

On the other hand, in FIG. 3, the first wiring layer 121 and the second wiring layer 122 are each illustrated as one wiring layer, but this is not necessarily limited. As the first insulating layer 111 and the second insulating layer 112 may be comprised of a plurality of insulating layers, the first wiring layer 121 and the second wiring layer 122 may each be comprised of a plurality of wiring layers if necessary. In addition, the thicknesses and pitches of the first wiring layer 121 and the second wiring layer 122 may not be substantially the same, and the second wiring layer 122 disposed above the glass layer 110 may be comprised of a redistribution layer, which is a thinner and finer pitch wiring layer for fine circuits. Additional configurations that may be used by those skilled in the art may also be included.

A printed circuit board according to some embodiments of the present disclosure may include a solder resist layer 150 on the outermost portion of the printed circuit board. The solder resist layer 150 may be disposed on the second insulating layer 112. The solder resist layer 150 may include an insulating material and a liquid or film type solder resist, but is not limited thereto, and other types of insulating materials may be used. The solder resist layer 150 may have at least one or more openings, and each of the openings may expose at least a portion of the second wiring layer 122.

Additionally, the printed circuit board according to some examples is not limited to the configuration illustrated in FIG. 3, and other configurations may be further included, or may be omitted in some cases. For example, the second insulating layer 112 may not be disposed below the glass layer 110, a plurality of first insulating layers 111 may be disposed, a cavity penetrating through at least a portion of the first insulating layer 111 or the second insulating layer 112 may be further formed, or a cavity penetrating through at least a portion of the glass layer 110 may be further formed, and electronic components may be mounted within the cavity. Alternatively, a surface treatment layer may be further formed on the wiring layer exposed through the opening of the solder resist layer 150, and in detail, it is not limited to the configuration illustrated in FIG. 3, and configurations that may be used in the art may further be included.

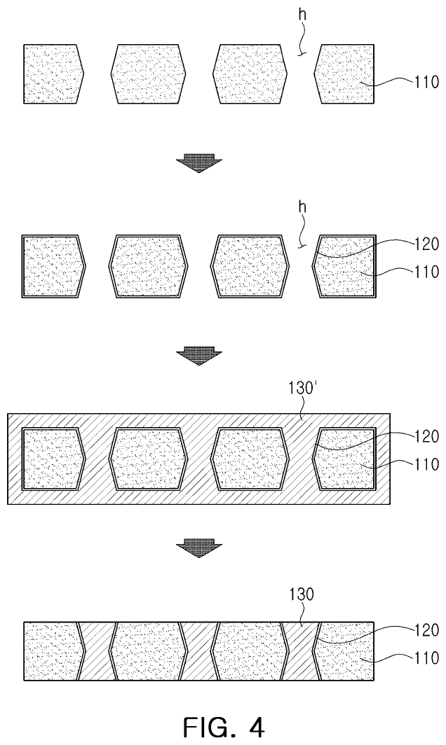

FIGS. 4 to 10 are cross-sectional views schematically illustrating various embodiments of the glass layer of a printed circuit board and a manufacturing method thereof. FIGS. 4 to 10 only illustrate various embodiments of the glass layer 110 and the through-via 130 of the printed circuit board and a manufacturing method thereof. Other components, such as the first insulating layer 111 and the like, may be formed by a known method after forming the glass layer 110 and the through-via 130 to complete the core layer. Thus, detailed information thereof will be omitted. Below, various embodiments of the glass layer 110 and the through-via 130 and the manufacturing methods thereof are described.

FIG. 4 illustrates a method of formula a through-hole h in the glass layer 110 according to some embodiments of the present disclosure. The through-hole h may be formed by various methods such as a laser processing, a mechanical processing, a chemical processing and the like, and the through-hole h may be formed by combining multiple processing methods rather than single a processing method. Alternatively, the method is not limited thereto, and any known method of forming a through-hole for a through glass via (TGV) penetrating through a glass layer may be used without limitation. The through-hole h may be formed from both the upper and lower portions of the glass layer 110. Accordingly, the through-hole h may have a tapered shape so that the width at the center of the glass layer 110 is narrowest and the widths at the top and bottom of the glass layer 110 are wider.

Subsequently, the seed layer 120 may be formed along a surface of the inner wall of the through-hole h and top and lower surfaces of the glass layer 111. As described above in the printed circuit board according to some examples, the seed layer 120 may include a conductive polymer material such as a carbon-based conductive material or a conductive polymer, and thus, the seed layer 120 may be formed by coating the glass layer 110 with a coating solution containing the material of the seed layer 120. Therefore, the method of forming the seed layer 120 may be performed at a lower cost than the process for forming the seed on a glass layer 110 of the related art, and the operation of forming the seed may be simplified and sufficient adhesion between the glass layer 110 and the seed layer 120 may be secured. At this time, as the method of forming the seed layer 120 progresses by a wet process, the seed layer 120 may be formed on the inner wall of the through-hole h of the glass layer 110, the seed layer 120 may also be formed on the top and bottom surfaces of the glass layer 110, and the seed layer 120 may also be formed on the outer side surfaces of the glass layer 110. In detail, the seed layer 120 may be formed on all surfaces of the glass layer 110 exposed externally. However, the present disclosure is not limited thereto, and in the case of forming the seed layer 120 by spraying a coating solution containing the material of the seed layer 120, the seed layer 120 may be formed only in the area adjacent to the inner wall of the through-hole h of the glass layer 110 by a method of targeting and spraying the inner wall of the through-hole h, or the like.

Afterwards, the through-via 130 is formed. The through-via 130 may be performed through a plating operation and a planarization operation.

In the through-via 130 plating operation, electroplating may be performed using the seed layer 120 as a plating lead-in line. As the seed layer 120 may be formed along the outer surface of the glass layer 110, a plating layer 130′ for the through-via may also be formed along the entire surface of the glass layer 110. For example, in the plating operation, after the plating layer 130′ fills the through-via 130, overplating is performed and may be placed on the upper and lower surfaces of the glass layer 110, and may also be disposed on the outer side surfaces of the glass layer 110.

Thereafter, operations may be performed to complete the through-via 130 by removing at least a portion of the plating layer 130′ and flattening the glass layer 110 and the through-via 130. The operation of removing at least a portion of the plating layer 130′ may be performed by a chemical-mechanical polishing (CMP) process, but is not necessarily limited thereto, and any method for flattening the glass layer 110, such as polishing or grinding, may be used without limitation. Additionally, an etching process to remove a portion of the plating layer may be further included before planarizing the glass layer 110 and the through-via 130. In the operation of planarizing the glass layer 110 and the through-via, a portion of the seed layer 120 may be removed, and the seed layer 120 disposed on the upper and lower surfaces of the glass layer 110 is removed to prevent short circuit due to the plating lead-in line, thereby functioning as a core layer of the printed circuit board. In this case, the upper surface of the glass layer 110, the upper surface of the through-via 130, and the upper surface of the seed layer 120 may provide a structure in which they are substantially coplanar with each other. As the seed layer 120 may include a carbon-based conductive material or a conductive polymer material such as a conductive polymer, adhesion with the glass layer 110 and adhesion between the glass layer and the seed layer 120 may be increased. In this case, in the case in which patterning is performed on the glass layer 110, it may be difficult to selectively remove only an unnecessary portion of the seed layer 120. Therefore, in this case, the through-via 130 may be completed by removing the seed layer 120 in batches while removing the plating layer 130′ disposed on the upper and lower surfaces of the glass layer 110 by chemical-mechanical polishing. However, the present disclosure is not necessarily limited thereto, and in a method of patterning the plating layer 130′ or in the patterning operation, the patterning method may also be possible using a plating resist, and patterning may also be performed on the glass layer 110 by removing a portion of the seed layer 120.

After completing the through-via 130 in the glass layer 110, operations to form other components of the printed circuit board, such as the first insulating layer 111 and the like, may be performed, which is the same as described above in the printed circuit board according to the example, and thus the description thereof is omitted.

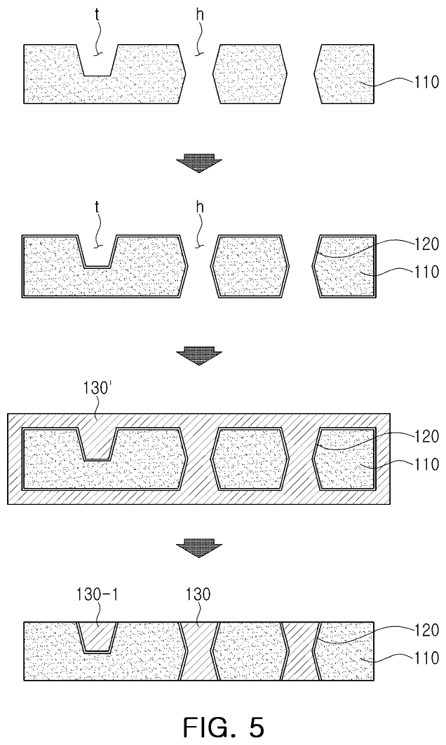

Referring to FIG. 5, when forming the through-hole h in the glass layer 110, a trench t penetrating through a portion of the glass layer 110 may be formed. The method of forming the trench t in the glass layer 110 may use a process similar to the method of forming a through-hole in the glass layer 110, and without being limited thereto, a known trench forming method may be used. The trench t does not completely penetrate the upper and lower surfaces of the glass layer 110, and may only penetrate a portion of the glass layer 110. The trench t may have a bottom surface, which may be a part of the glass layer 110, and may have a tapered shape so that the width of the bottom surface of the trench t is narrower than the width of the upper surface. However, the trench t is not limited thereto, and may have a shape of a pillar formed so as not to be tapered. In FIG. 5, the depth of the trench t is illustrated to be a half of the depth of the through-via 130, but the present disclosure is not limited thereto. The depth of the trench t may be less than a half of the depth of the through-via 130. In this manner, the shape of the trench t is not limited, and may be sufficient if the glass layer 110 consists of an empty space to implement a filling pattern.

Next, after forming the trench t, the seed layer 120 may be further formed on the inner wall and bottom surface of the trench t. In the subsequent plating operation, a plating layer 130′ may be formed to fill the trench t. By removing a portion of the plating layer 130′, a filling pattern 130-1 that fills the trench t may be formed. The filling pattern 130-1 may be formed in the same manner as the through-via 130 and may include the same metal. The filling pattern 130-1 may have various shapes and perform various functions. Descriptions of the shape and function of the wiring layer may be applied to the shape and function of the filling pattern 130-1. The filling pattern 130-1 may be embedded so that the remaining surfaces except the upper surface are covered by the glass layer 110, and a seed layer 120 may be disposed between the filling pattern 130-1 and the glass layer 110. If necessary, a first via layer 131 may be formed on the filling pattern 130-1 and connected to the first wiring layer 121. The fact that the filling pattern 130-1 may be connected to the first wiring layer 121 may be the same as the manner in which the through-via 130 may be connected to the first wiring layer 121.

Among the descriptions other than the configuration of forming the trench t in the operation of forming the through-hole h, the operation of forming the seed layer 120 and the operation of completing the through-via 130 after plating are the same as described above, and thus redundant descriptions related thereto will be omitted.

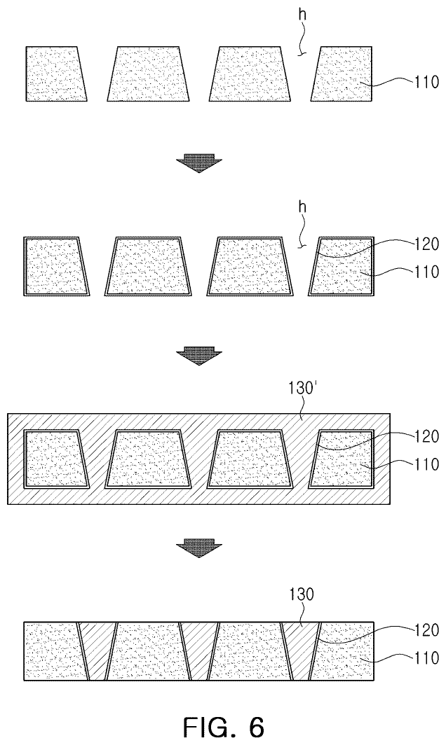

Referring to FIG. 6, the through-hole h formed in the glass layer 110 may have a tapered shape so that the width of the lower surface of the through-hole is narrower than the width of the upper surface of the through-hole. This may be the result of processing the through-hole h from the upper side of the glass layer 110 rather than processing the through-holes h from both the upper and lower surfaces of the glass layer 110. However, the present disclosure is not limited thereto, and the through-hole h may have a non-tapered pillar shape. As described above in the printed circuit board as an example, the shape of the through-via 130 may be determined depending on the shape of the through-hole h.

Among the descriptions other than the shape of the through-hole h, the operation of forming the seed layer 120 and the operation of completing the through-via 130 after plating are the same as described above, and thus redundant description thereof will be omitted.

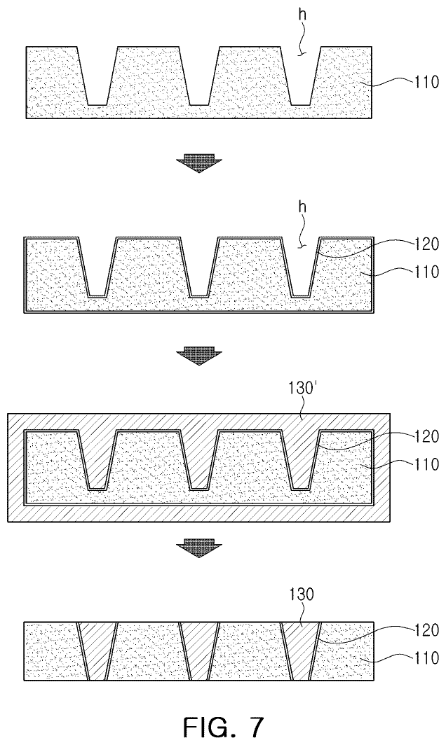

Referring to FIG. 7, the through-hole h formed in the glass layer 110 may not completely penetrate the upper and lower surfaces of the glass layer 110. The through-hole h may only penetrate a portion of the glass layer 110 from the top surface to a middle of the glass layer 110. For example, through-hole h may include a bottom surface that is the a part of the glass layer 110. After forming the through-hole h, the seed layer 120 may be disposed on the side wall of the through-hole and also on the bottom surface of the through-hole h. After forming the plating layer 130′, the glass layer 110 and the plating layer 130′ may be removed by removing the lower portion of the glass layer 110, the lower surface of the through-via 130 may be exposed to the lower surface of the glass layer 110. By removing the lower portion of the glass layer 110, a structure in which the lower surface of the through-via 130 is exposed externally may be provided.

Among the descriptions other than the shape of the through-via 130 and the manufacturing method thereof, the operation of forming the seed layer 120 and the operation of completing the through-via 130 after plating are the same as described above, and thus duplicate descriptions thereof will be omitted.

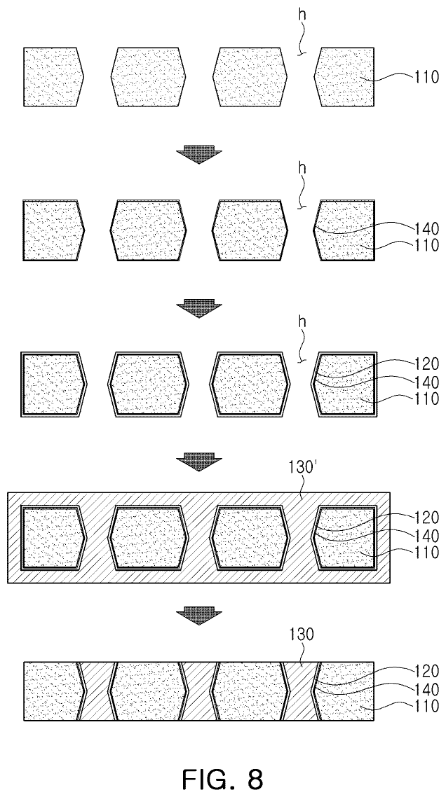

Referring to FIG. 8, after forming the through-hole h in the glass layer 110, an adhesive layer 140 may be formed along the inner wall of the through-hole h. After forming the adhesive layer 140, the seed layer 120 may be disposed on the adhesive layer 140. For example, the adhesive layer 140 is disposed on the inner wall of the through-hole h and may be disposed between the through-hole h and the seed layer 120.

The adhesive layer 140 may be an organic thin film containing a silane coupling agent, but is not necessarily limited thereto, and any adhesive materials available in the art may be used without limitation. The silane coupling agent may contain at least one type selected from among silanes such as acryl-based silane, epoxy-based silane, amino-based silane, imidazole-based silane, or mercapto-based silane, but the present disclosure is not limited thereto. The adhesive layer 140 is located between the glass layer 110 and the seed layer 120, and may increase the adhesion between the glass layer 110 and the seed layer 120, which may provide the effect of increasing adhesion between the through-via 130 and the glass layer 110. Any known adhesive layer forming method may be used without limitation to form the adhesive layer 140. In the operation of forming the adhesive layer 140, the adhesive layer 140 may be formed on the upper and lower surfaces of the glass layer 110, and may also be formed on the outer side surfaces of the glass layer 110.

Thereafter, the operations of forming the seed layer 120, performing plating, and flattening the glass layer 110 are the same as described above, and thus redundant description thereof will be omitted.

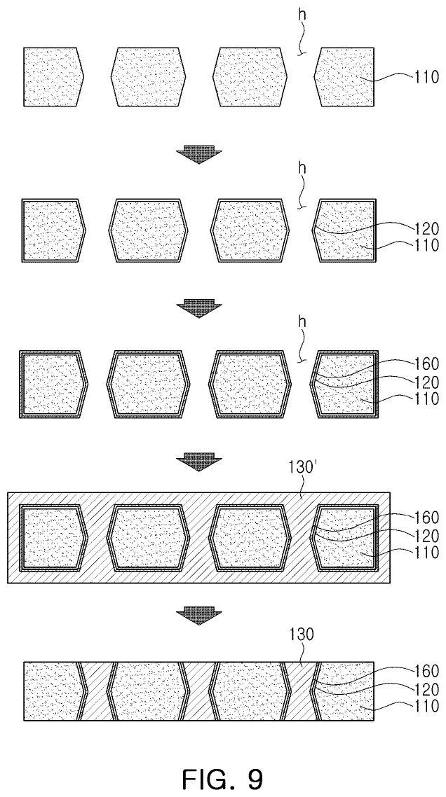

Referring to FIG. 9, after forming the seed layer 120 on the inner wall of the through-hole h of the glass layer 110, a first metal layer 160 may be formed. The first metal layer 160 may be disposed on the seed layer 120 and disposed along the shape of the inner wall of the through-hole h. For example, the first metal layer 160 may be disposed between the through-via 130 and the seed layer 120.

The first metal layer 160 may include a metal, and examples of the metal may include at least one selected from the group consisting of copper (Cu), aluminum (Al), silver (Ag), tin (Sn), gold (Au), nickel (Ni), lead (Pb), titanium (Ti), and alloys thereof, and in detail, may include copper (Cu), but are not limited thereto. The first metal layer 160 may be formed through electroless plating, but is not necessarily limited thereto and may be formed through sputtering. The first metal layer 160 may be a single metal layer, but is not limited thereto and may include a plurality of metal layers. Since the first metal layer 160 may be disposed on the seed layer 120, adhesion between the first metal layer 160 and the seed layer may be higher than when the first metal layer 160 is placed directly on the glass layer. This is because the adhesion between the seed layer 120 and the first metal layer 160 is superior to adhesion between the first metal layer 160 and the glass layer 110. The first metal layer 160 may include an electroless plating layer, and may thus be disposed along the outer surface of the glass layer 110 on the seed layer 120, and the first metal layer 160 assists the seed layer 120, which functions as a plating lead-in line, to perform the function of the plating lead-in line more effectively.

Thereafter, the operations of performing plating and flattening the glass layer 110 are the same as described above, and thus redundant description thereof will be omitted.

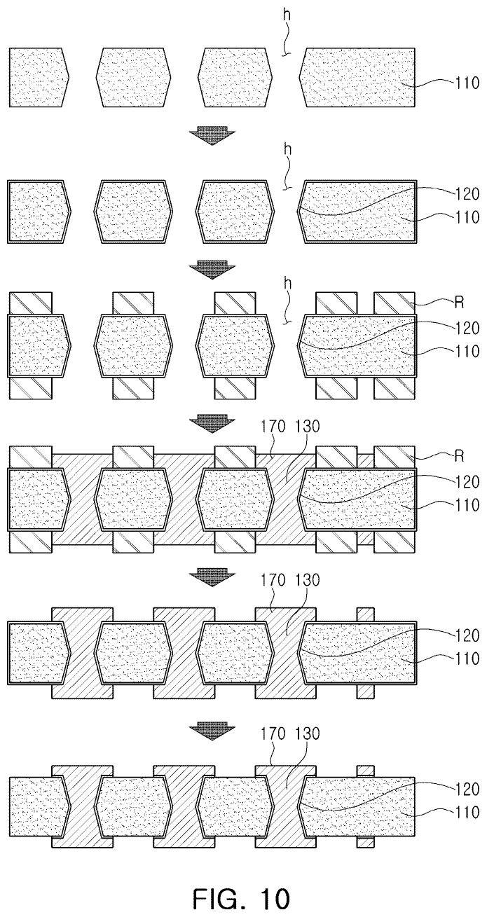

Referring to FIG. 10, after forming the seed layer 120 along the glass layer 110, an operation of forming and patterning a plating resist R may be included. The plating resist R performs a function of preventing plating from growing during electroplating, and a known plating resist may be used.

When plating is performed after forming the plating resist R, electrolytic plating may be performed only on areas where the plating resist R is not formed, and a pattern layer disposed above and below the glass layer 110 may be further formed along with the through-via 130. The pattern layer 170 may be formed on the upper and lower surfaces of the through-via 130, and may also be formed on the upper and lower surfaces of the glass layer 110. A seed layer 120 may be disposed between the pattern layer 170 and the glass layer 110. Since the pattern layer 170 is formed together with the through-via 130 in the operation of forming the through-via 130, the pattern layer 170 and the through-via 130 may include metal of substantially the same material, and the boundary between the pattern layer 170 and the through-via 130 may not be clear, and the pattern layer 170 and the through-via 130 may be formed integrally.

After forming the pattern layer 170, the plating resist R may be removed. The removing the plating resist R may be performed using a well-known method in the art.

After removing the plaiting resist R, a portion of the seed layer 120 may be removed. At this time, the seed layer 120 in the area where the pattern layer 170 is not formed is removed to open the space between adjacent patterns to function as a circuit pattern. This may be the result of introducing a method of selectively removing the seed layer 120, rather than removing the entirety of the seed layer 120 disposed on the glass layer 110, between the seed layer 120 and the glass layer 110. The method of selectively removing a portion of the seed layer 120 may be performed by processing only a portion of the seed layer 120 through a mask, but the present disclosure is not limited thereto. Since the seed layer 120 does not contain metal, the through-via 130 and the pattern layer 170 may be less damaged during the operation of removing the seed layer 120, and the seed layer 120 of only the targeted area may be effectively removed.

On the other hand, the configuration other than the pattern layer 170 formed by the plating resist R is the same as described above, and thus redundant description thereof will be omitted.

On the other hand, in FIGS. 4 to 10, various embodiments of the glass layer 110 and the through-via 130 and forming methods thereof are described, but respective embodiments are not limited to only one embodiment, of course. For example, an adhesive layer 140 is included and a first metal layer 160 may further be provided, and various configurations, such as the pattern layer 170, the filling pattern 130-1 and the like, may be implemented respectively, independently of each other in one glass layer 110.

As set forth above, a printed circuit board including a glass layer may be provided.

A printed circuit board in which adhesion between a glass layer and a metal material may be secured may be provided.

A printed circuit board having improved reliability may be provided.

In the present disclosure, the expression, “cover” may include not only the case of covering the whole, but also the case of covering at least a portion, and may also include indirect covering as well as cases of direct covering. In addition, the expression to fill may include not only completely filling but also approximately filling, and for example, may include cases where some voids or voids are present.

In the present disclosure, the judgment may actually include process errors, position deviations, errors during measurement, and the like that occur during the manufacturing process. For example, “substantially vertical” may include not only completely vertical, but also approximately vertical. In addition, being substantially coplanar may include not only cases of being completely on the same plane, but also cases of being approximately on the same plane.

In the present disclosure, the same insulating material may mean not only the exact same insulating material but also including the same type of insulating material. Therefore, the composition of the insulating materials is substantially the same, but their specific composition ratios may vary slightly.

In the present disclosure, the meaning of “cross-section” may mean the cross-sectional shape when the object is cut vertically, or the cross-sectional shape when the object is viewed from a side surface view. In addition, the meaning of “on a plane” may mean a plane shape when the object is cut horizontally, or a plane shape when the object is viewed from a top-view or bottom-view.

In the present disclosure, lower side, lower portion, bottom, lower surface, and the like are used for convenience to mean a downward direction based on the cross section of the drawing. Upper side, upper portion, upper surface, top, and the like are used to mean the opposite direction. However, this direction is defined for convenience of explanation, and of course, the scope of the patent claims is not particularly limited by the description of this direction. The concept of top/bottom may change at any time.

In the present disclosure, the meaning of connected is a concept that includes not only directly connected, but also indirectly connected through an adhesive layer or the like. In addition, the meaning of being electrically connected is a concept that includes both cases where it is physically connected and cases where it is not connected. Additionally, expressions such as first, second, and the like are used to distinguish one component from another component and do not limit the order and/or importance of the components, and the like. In some cases, the first component may be named the second component, and similarly, the second component may be named as the first component, without departing from the scope of rights.

The expression ‘example’ used in the present disclosure does not mean identical embodiments, but is provided to emphasize and explain different unique features. However, the examples presented above do not exclude being implemented in combination with features of other examples. For example, even if what is described in an example is not described in another example, unless there is a contrary or contradictory explanation in another example, it may be understood as an explanation related to another example.

The terminology used in this disclosure is used to describe examples only and is not intended to limit the disclosure. At this time, singular expressions include plural expressions, unless the context clearly indicates otherwise.

While example embodiments have been illustrated and described above, it will be apparent to those skilled in the art that modifications and variations could be made without departing from the scope of the present invention as defined by the appended claims.

What is claimed is:

1. A printed circuit board comprising:
a glass layer;
a through-hole penetrating through the glass layer;
a seed layer disposed on a surface of an inner wall of the through-hole; and
a through-via disposed on the seed layer and filling the through-hole,
wherein the seed layer includes a carbon-based conductive material.

2. The printed circuit board of claim 1, wherein the seed layer includes at least one material selected from the group consisting of carbon black, graphite, graphene, carbon nanotube (CNT), and fullerene.

3. The printed circuit board of claim 1, wherein the through-hole has a tapered shape having a narrowest width at a central portion of the glass layer in a thickness direction and widths that are increased gradually from the narrowest width toward both an upper surface and a lower surface of the glass layer.

4. The printed circuit board of claim 1, wherein the through-hole has a tapered shape with a width that is increase gradually from a lower surface toward an upper surface of the glass layer.

5. The printed circuit board of claim 1, wherein an upper surface of the through-via is substantially coplanar with an upper surface of the glass layer.

6. The printed circuit board of claim 5, wherein a lower surface of the through-via is substantially coplanar with a lower surface of the glass layer.

7. The printed circuit board of claim 1, wherein an upper surface and a lower surface of the seed layer are substantially coplanar with an upper surface and a lower surface of the glass layer, respectively.

8. The printed circuit board of claim 1, further comprising an adhesive layer disposed between the inner wall of the through-hole and the seed layer.

9. The printed circuit board of claim 8, wherein the adhesive layer contains a silane-based coupling agent.

10. The printed circuit board of claim 1, further comprising a first metal layer interposed between the seed layer and the through-via.

11. The printed circuit board of claim 10, wherein the first metal layer includes substantially the same metal material as a material included in the through-via.

12. The printed circuit board of claim 1, further comprising:
a trench penetrating through a portion of the glass layer; and
a filling pattern embedded in the glass layer and filling the trench.

13. The printed circuit board of claim 12, wherein the seed layer is disposed on a surface of an inner wall and a bottom surface of the trench.

14. The printed circuit board of claim 1, further comprising a pattern layer disposed on the through-via and extending onto at least a portion of an upper surface of the glass layer,
wherein the seed layer extends onto at least a portion of the upper surface of the glass layer.

15. The printed circuit board of claim 1, further comprising:
a first insulating layer disposed on the glass layer; and
a first wiring layer disposed on the first insulating layer.

16. A printed circuit board comprising:
a glass layer;
a through-via penetrating through an upper surface and a lower surface of the glass layer; and
a seed layer disposed between the through-via and the glass layer,
wherein the seed layer includes at least one of a conductive polymer material or a carbon-based conductive material, and
an upper surface of the through-via is substantially coplanar with the upper surface of the glass layer.

17. The printed circuit board of claim 16, further comprising an adhesive layer disposed between the inner wall of the glass layer and the seed layer.

18. The printed circuit board of claim 16, further comprising a first metal layer interposed between the seed layer and the through-via.

19. The printed circuit board of claim 1, further comprising:
a first insulating layer disposed on the glass layer; and
a first wiring layer disposed on the first insulating layer.
